(19) United States
(12) Patent Application Publication
(10) Pub. No.: US 2022/0117071 A1
(43) Pub. Date: Apr. 14, 2022

(54) APPARATUS AND METHOD FOR TREATING SUBSTRATE

(71) Applicant: SEMES CO., LTD., Cheonan-si (KR)

(72) Inventor: Jun Young CHOI, Cheongju-si (KR)

(73) Assignee: SEMES CO., LTD., Cheonan-si (KR)

(21) Appl. No.: 17/467,962

(22) Filed: Sep. 7, 2021

(30) Foreign Application Priority Data
Oct. 12, 2020 (KR) 10-2020-0131363

(51) Int. Cl. H05F 3/02; H01L 21/67; H01L 21/687

(52) U.S. Cl. CPC H05F 3/02; H01L 21/6875; H01L 21/67288; H01L 21/67051

(57) ABSTRACT

A method for treating a substrate includes treating the substrate by dispensing a chemical solution onto the substrate while rotating the substrate, in which a grounded conductive member that makes direct contact with the substrate or the chemical solution is included in a support unit that supports and rotates the substrate, a current detector is provided on a ground path between the grounded conductive member and a ground, and a treatment condition for the substrate is controlled based on a current value detected by the current detector.

### CROSS-REFERENCE TO RELATED APPLICATIONS

A claim for priority under 35 U.S.C. § 119 is made to Korean Patent Application No. 10-2020-0131363 filed on Oct. 12, 2020, in the Korean Intellectual Property Office, the entire contents of which are hereby incorporated by reference.

### BACKGROUND

Embodiments of the inventive concept described herein relate to an apparatus and method for treating a substrate such as a wafer.

In general, semiconductor devices are manufactured by depositing various materials on a substrate in thin film forms and subjecting the thin films to patterning. To this end, various processes such as a deposition process, a photolithography process, an etching process, a cleaning process, and the like are required.

Among these processes, the etching process is a process of removing a film formed on a substrate, and the cleaning process is a process of removing residual contaminants on a substrate after each of unit processes for manufacturing semiconductor devices. Etching processes and cleaning processes are classified into wet processes and dry processes, and the wet processes are classified into a batch type process and a spin type process.

In the spin type process, a substrate is clamped to a support unit capable of supporting one substrate, and a chemical solution dispensing nozzle dispenses a chemical solution (e.g., an etching solution, a cleaning solution, or a rinsing solution) onto the rotating substrate. The chemical solution dispensed onto the substrate is spread over the entire surface of the substrate by a centrifugal force to clean the substrate. After the cleaning of the substrate, the substrate is dried by various methods.

A spin type substrate treating apparatus performs a cleaning process on a substrate while rotating the substrate and static electricity is generated by a chemical solution dispensed onto the rotating substrate and other causes. The static electricity adversely affects equipment operation and the substrate (e.g., arcing damage or particle re-adhesion). To solve this problem, a chucking pin and a rotary shaft are connected by a conductive line, and electric charges charged on the substrate are released to the outside through the chucking pin and the rotary shaft. Accordingly, damage to the substrate due to arcing damage and particle re-adhesion due to static electricity may be prevented.

### SUMMARY

Embodiments of the inventive concept provide a substrate treating apparatus and method for improving efficiency in treating a substrate.

Embodiments of the inventive concept provide a substrate treating apparatus and method for obtaining data including information about a substrate from a component applied to release static electricity generated by a chemical solution dispensed onto the rotating substrate and other causes and utilizing the obtained data.

The technical problems to be solved by the inventive concept are not limited to the aforementioned problems, and any other technical problems not mentioned herein will be clearly understood from the following description by those skilled in the art to which the inventive concept pertains.

According to an embodiment, an apparatus for treating a substrate includes a cup having a process space therein, a support unit that supports the substrate in the process space and that includes a rotatable support plate, a chemical solution dispensing unit that dispenses a chemical solution onto the substrate supported on the support unit, and a conductive member that makes direct contact with at least one of the substrate or the chemical solution dispensed onto the substrate. The conductive member is grounded, and a current detector is provided on a ground path between the grounded conductive member and a ground.

In an embodiment, the conductive member may be a chucking pin that supports a side surface of the substrate.

In an embodiment, the support unit may include a plurality of support pins that are provided on the support plate and that support the substrate located above the support plate, and the conductive member may be implemented with at least one of the support pins.

In an embodiment, the current detector may be implemented with a high-sensitivity element that measures current in nano Ampere (nA) or less.

In an embodiment, the support plate may be rotatable at a first rotational speed and a second rotational speed lower than the first rotational speed.

In an embodiment, the chemical solution dispensing unit may dispense two or more different chemical solutions.

In an embodiment, the current detector may detect a current value in real time while the chemical solution is dispensed onto the substrate.

In an embodiment, the apparatus may further include a data processing unit that processes a current value detected by the current detector.

In an embodiment, the data processing unit may determine that the substrate is defective, when the detected current value is greater than or equal to a preset threshold value.

In an embodiment, the chemical solution dispensing unit may dispense a first chemical solution and a second chemical solution different from the first chemical solution, and the first chemical solution dispensed onto the substrate may be substituted with the second chemical solution. The data processing unit may determine that the first chemical solution is substituted with the second chemical solution, when a change in the detected current value is greater than or equal to a preset value in a process in which the first chemical solution is substituted with the second chemical solution.

In an embodiment, the data processing unit may determine that the substrate is completely treated with the chemical solution, when a change in the detected current value is greater than or equal to a preset value in a process in which the substrate is treated with the chemical solution.

According to an embodiment, a method for treating a substrate includes treating the substrate by dispensing a chemical solution onto the substrate while rotating the substrate, in which a grounded conductive member that makes direct contact with the substrate or the chemical solution is included in a support unit that supports and rotates the substrate, a current detector is provided on a ground path between the grounded conductive member and a ground, and a treatment condition for the substrate is controlled based on a current value detected by the current detector.

In an embodiment, the current detector may be implemented with a high-sensitivity element that measures current in nano Ampere (nA) or less.

In an embodiment, the current detector may detect a current value in real time while the chemical solution is dispensed onto the substrate.

In an embodiment, the substrate may be determined to be defective, when the detected current value is greater than or equal to a preset threshold value.

In an embodiment, the substrate may be treated with a first chemical solution and a second chemical solution different from the first chemical solution, the first chemical solution dispensed onto the substrate may be substituted with the second chemical solution, and it may be determined that the first chemical solution is substituted with the second chemical solution, when a change in the detected current value is greater than or equal to a preset value in a process in which the first chemical solution is substituted with the second chemical solution.

In an embodiment, it may be determined that the substrate is completely treated, when a change in the detected current value is greater than or equal to a preset value in a process in which the substrate is treated with the chemical solution.

In an embodiment, the conductive member may include a chucking pin that supports a side surface of the substrate and at least one of support pins that support a bottom surface of the substrate.

According to an embodiment, an apparatus for treating a substrate includes a cup having a process space therein, a support unit that supports the substrate in the process space and that includes a support plate rotatable at a first rotational speed and a second rotational speed lower than the first rotational speed, and a chemical solution dispensing unit that dispenses a first chemical solution and a second chemical solution different from the first chemical solution onto the substrate supported on the support unit. The support unit further includes a chucking pin that supports a side surface of the substrate and a plurality of support pins that are provided on the support plate and that support the substrate located above the support plate. The chucking pin and at least one of the plurality of support pins are grounded. The apparatus further includes a current detector that is provided on a ground path between the grounded chucking pin or the at least one grounded support pin and a ground and that measures current in nano Ampere (nA) or less and a data processing unit that processes a current value detected by the current detector.

In an embodiment, the current detector may detect a current value in real time while the first or second chemical solution is dispensed onto the substrate. The data processing unit may determine that the substrate is completely treated with the first chemical solution, when a change in the detected current value is greater than or equal to a preset value in a process in which the substrate is treated with the first chemical solution and may determine that the first chemical solution is substituted with the second chemical solution, when a change in the detected current value is greater than or equal to a preset value in a process in which the first chemical solution is substituted with the second chemical solution.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a schematic plan view illustrating substrate treating equipment according to an embodiment of the inventive concept;

FIG. 2 is a schematic sectional view illustrating a substrate treating apparatus according to an embodiment;

FIG. 3 is a schematic plan view illustrating a support unit provided in the substrate treating apparatus of FIG. 2;

FIG. 4 is a schematic sectional view illustrating the inside of the support unit provided in the substrate treating apparatus of FIG. 2;

FIG. 5 is a view illustrating a state in which a first chemical solution is dispensed onto a substrate supported on the support unit provided in the substrate treating apparatus according to the embodiment of FIG. 2;

FIG. 6 is a view illustrating a state in which a second chemical solution is dispensed onto the substrate supported on the support unit provided in the substrate treating apparatus according to the embodiment of FIG. 2;

FIG. 7 is a view illustrating a state in which the first chemical solution is dispensed when a substrate supported on the support unit provided in the substrate treating apparatus according to the embodiment of FIG. 2 rotates at a first rotational speed;

FIG. 8 is a view illustrating a state in which the first chemical solution is dispensed when the substrate supported on the support unit provided in the substrate treating apparatus according to the embodiment of FIG. 2 rotates at a second rotational speed;

FIG. 9 is a graph depicting the amounts of current by electric charges escaping through a ground;

FIG. 10 is a view illustrating a state in which a third chemical solution is dispensed onto a substrate supported on the support unit provided in the substrate treating apparatus according to the embodiment of FIG. 2; and

FIG. 11 is a view illustrating a state in which a film is changed by the third chemical solution continually dispensed in the state of FIG. 10.

### DETAILED DESCRIPTION

The above and other aspects, features, and advantages of the inventive concept will become apparent from the following description of embodiments given in conjunction with the accompanying drawings. However, the inventive concept is not limited to the embodiments disclosed herein, and the scope of the inventive concept should be limited only by the accompanying claims and equivalents thereof. Unless otherwise defined, all terms used herein, including technical or scientific terms, have the same meanings as those generally understood by those skilled in the art to which the inventive concept pertains. General descriptions related to well-known configurations will be omitted when they may make subject matters of the inventive concept unnecessarily obscure. Identical reference numerals are used to refer to identical or corresponding components in the drawings of the inventive concept if possible.

The terminology used herein is for the purpose of describing particular embodiments only and is not intended to limit the scope of the inventive concept. The terms of a singular form may include plural forms unless otherwise specified. It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Hereinafter, embodiments of the inventive concept will be described in more detail with reference to the accompanying drawings. The inventive concept may, however, be embodied in different forms and should not be construed as limited to the embodiments set forth herein. Rather, these embodiments are provided so that the inventive concept will be thorough and complete, and will fully convey the scope of the inventive concept to those skilled in the art. In the drawings, the dimensions of components are exaggerated and reduced for clarity of illustration.

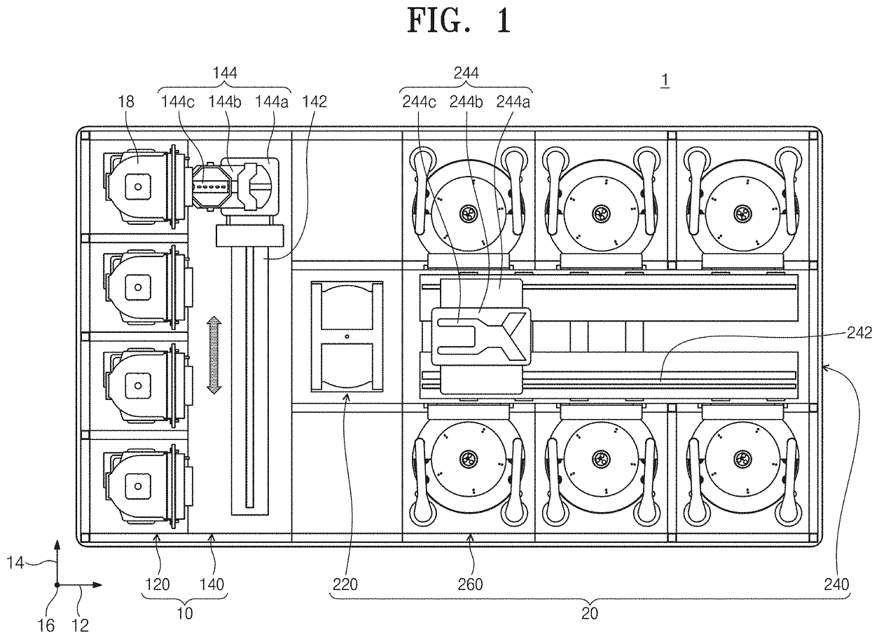

FIG. 1 is a schematic plan view illustrating substrate treating equipment 1 according to an embodiment of the inventive concept.

Referring to FIG. 1, the substrate treating equipment 1 has an index module 10 and a process module 20. The index module 10 has a load port 120 and a transfer frame 140. The load port 120, the transfer frame 140, and the process module 20 are sequentially arranged in a row. Hereinafter, a direction in which the load port 120, the transfer frame 140, and the process module 20 are arranged is referred to as a first direction 12, a direction perpendicular to the first direction 12 when viewed from above is referred to as a second direction 14, and an upward direction perpendicular to a plane including the first direction 12 and the second direction 14 is referred to as a third direction 16.

A carrier 18 having substrates W received therein is seated on the load port 120. A plurality of load ports 120 may be provided. The load ports 120 may be disposed in a row in the second direction 14. The number of load ports 120 may be increased or decreased depending on the process efficiency and footprint condition of the process module 20. The carrier 18 has a plurality of slots (not illustrated) formed therein in which the substrates W are received in a state of being horizontally disposed with respect to the ground. A front opening unified pod (FOUP) may be used as the carrier 18.

The process module 20 has a buffer unit 220, a transfer chamber 240, and process chambers 260. The transfer chamber 240 is disposed such that the lengthwise direction thereof is parallel to the first direction 12. The process chambers 260 are disposed on opposite sides of the transfer chamber 240. On the opposite sides of the transfer chamber 240, the process chambers 260 are provided to be symmetric with respect to the transfer chamber 240. The process chambers 260 are provided on one side of the transfer chamber 240. Some of the process chambers 260 are disposed along the lengthwise direction of the transfer chamber 240. Furthermore, other process chambers 260 are stacked one above another. That is, the process chambers 260 may be disposed in an A×B array on the one side of the transfer chamber 240. Here, “A” denotes the number of process chambers 260 provided in a row along the first direction 12, and “B” denotes the number of process chambers 260 provided in a column along the third direction 16. When four or six process chambers 260 are provided on the one side of the transfer chamber 240, the process chambers 260 may be disposed in a 2×2 or 3×2 array. The number of process chambers 260 may be increased or decreased. Alternatively, the process chambers 260 may be provided on only the one side of the transfer chamber 240. In another case, the process chambers 260 may be disposed in a single layer on the opposite sides of the transfer chamber 240.

The buffer unit 220 is disposed between the transfer frame 140 and the transfer chamber 240. The buffer unit 220 provides a space in which the substrates W stay before transferred between the transfer chamber 240 and the transfer frame 140. The buffer unit 220 has a plurality of slots (not illustrated) in which the substrates W are placed. The slots (not illustrated) are spaced apart from each other along the third direction 16. The buffer unit 220 is open at one side facing the transfer frame 140 and at an opposite side facing the transfer chamber 240.

The transfer frame 140 transfers the substrates W between the carriers 18 placed on the load ports 120 and the butter unit 220. An index rail 142 and an index robot 144 are provided in the transfer frame 140. The index rail 142 is disposed such that the lengthwise direction thereof is parallel to the second direction 14. The index robot 144 is installed on the index rail 142 and rectilinearly moves along the index rail 142 in the second direction 14. The index robot 144 has a base 144a, a body 144b, and an index arm 144c. The base 144a is movable along the index rail 142. The body 144b is coupled to the base 144a. The body 144b is movable on the base 144a along the third direction 16. Furthermore, the body 144b is rotatable on the base 144a. The index arm 144c is coupled to the body 144b and is movable forward and backward relative to the body 144b. A plurality of index arms 144c may be provided. The index arms 144c may be individually driven. The index arms 144c are stacked one above another with a spacing gap therebetween along the third direction 16. Some of the index arms 144c may be used to transfer the substrates W from the process module 20 to the carriers 18, and the other index arms 144c may be used to transfer the substrates W from the carriers 18 to the process module 20. Accordingly, particles generated from the substrates W to be treated may be prevented from adhering to the treated substrates W in a process in which the index robot 144 transfers the substrates W between the carriers 18 and the process module 20.

The transfer chamber 240 transfers the substrates W between the buffer unit 220 and the process chambers 260 and between the process chambers 260. A guide rail 242 and a main robot 244 are provided in the transfer chamber 240. The guide rail 242 is disposed such that the lengthwise direction thereof is parallel to the first direction 12. The main robot 244 is installed on the guide rail 242 and rectilinearly moves on the guide rail 242 along the first direction 12. The main robot 244 has a base 244a, a body 244b, and a main arm 244c. The base 244a is movable along the guide rail 242. The body 244b is coupled to the base 244a. The body 244b is movable on the base 244a along the third direction 16. Furthermore, the body 244b is rotatable on the base 244a. The main arm 244c is coupled to the body 244b and is movable forward and backward relative to the body 244b. A plurality of main arms 244c may be provided. The main arms 244c may be individually driven. The main arms 244c are stacked one above another with a spacing gap therebetween along the third direction 16.

Substrate treating apparatuses 3000 for performing cleaning processes on substrates W are provided in the process chambers 260, respectively. The substrate treating apparatuses 3000 may have different structures depending on the types of cleaning processes performed therein. Alternatively, the substrate treating apparatuses 3000 in the respective process chambers 260 may have the same structure. Selectively, the process chambers 260 may be divided into a plurality of groups. The substrate treating apparatuses 3000 in the process chambers 260 belonging to the same group may have the same structure, and the substrate treating apparatuses 3000 in the process chambers 260 belonging to different groups may have different structures. For example, in the case where the process chambers 260 are divided into two groups, a first group of process chambers 260 may be disposed on the one side of the transfer chamber 240, and a second group of process chambers 260 may be disposed on the opposite side of the transfer chamber 240. Selectively, on the opposite sides of the transfer chamber 240, the first group of process chambers 260 may be disposed in a lower layer, and the second group of process chambers 260 may be disposed in an upper layer. The first group of process chambers 260 may be distinguished from the second group of process chambers 260 depending on the types of chemical solutions used or the types of cleaning methods. In contrast, the first group of process chambers 260 and the second group of process chambers 260 may sequentially perform processes on one substrate W. For example, the substrate W may be subjected to a chemical solution treatment process or a rinsing process in the first group of process chambers 260 and may be subjected to a rinsing process or a drying process in the second group of process chambers 260.

Hereinafter, an embodiment of the substrate treating apparatus 3000 that cleans a substrate W using chemical solutions will be described. The substrate treating apparatus 3000 performs chemical solution treatment on the substrate W. The chemical solutions may include a phosphoric acid solution, a sulfuric acid solution, hydrofluoric acid, deionized water (DIW), water containing CO₂, or IPA.

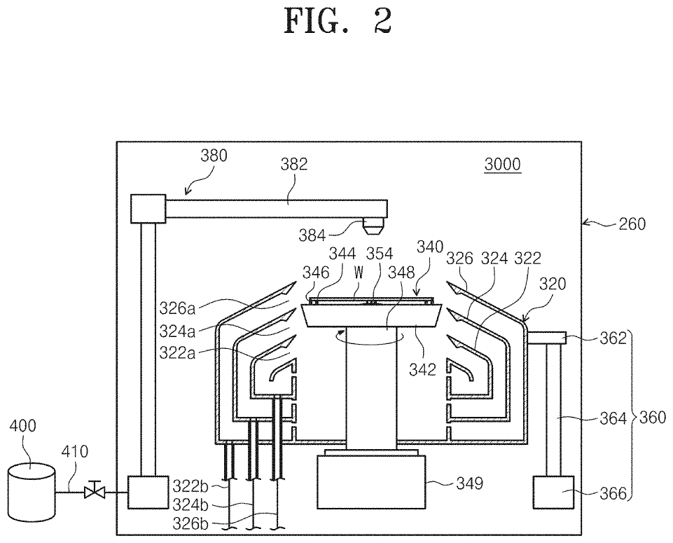

FIG. 2 is a schematic sectional view illustrating the substrate treating apparatus 3000.

The substrate treating apparatus 3000 is provided in the process chamber 260.

The substrate treating apparatus 3000 includes a cup 320, a support unit 340, a lifting unit 360, and a chemical solution dispensing unit 380.

The cup 320 has a process space in which a substrate treating process is performed. The cup 320 is open at the top thereof. The cup 320 has an inner recovery bowl 322, an intermediate recovery bowl 324, and an outer recovery bowl 326. The recovery bowls 322, 324, and 326 recover different chemical solutions used for the substrate treating process. The inner recovery bowl 322 has an annular ring shape surrounding the support unit 340. The intermediate recovery bowl 324 has an annular ring shape surrounding the inner recovery bowl 322. The outer recovery bowl 326 has an annular ring shape surrounding the intermediate recovery bowl 324.

An inner space 322a of the inner recovery bowl 322, a space 324a between the inner recovery bowl 322 and the intermediate recovery bowl 324, and a space 326a between the intermediate recovery bowl 324 and the outer recovery bowl 326 function as inlets through which the chemical solutions flow into the inner recovery bowl 322, the intermediate recovery bowl 324, and the outer recovery bowl 326. Recovery lines 322b, 324b, and 326b vertically extend downward from the bottoms surfaces of the recovery bowls 322, 324, and 326. The recovery lines 322b, 324b, and 326b discharge the chemical solutions introduced into the recovery bowls 322, 324, and 326. The discharged chemical solutions may be reused through an external chemical-solution regeneration system (not illustrated).

The lifting unit 360 rectilinearly moves the cup 320 in an up/down direction. As the cup 320 is moved in the up/down direction, the height of the cup 320 relative to the support unit 340 is changed. The lifting unit 360 has a bracket 362, a movable shaft 364, and an actuator 366. The bracket 362 is fixed to an outer wall of the cup 320, and the movable shaft 364, which is moved in the up/down direction by the actuator 366, is fixedly coupled to the bracket 362. When a substrate W is placed on the support unit 340 or lifted upward from the support unit 340, the cup 320 is moved downward to allow the support unit 340 to protrude above the cup 320. Furthermore, when the substrate treating process is performed, the height of the cup 320 is adjusted depending on the types of chemical solutions dispensed onto the substrate W, such that the chemical solutions are introduced into the preset recovery bowls 322, 324, and 326. Selectively, the lifting unit 360 may move the support unit 340 in the up/down direction.

The chemical solution dispensing unit 380 dispenses a chemical solution onto the substrate W during the substrate treating process. The chemical solution dispensing unit 380 has a support shaft 386, an actuator 388, a nozzle support rod 382, and a nozzle 384. The support shaft 386 is disposed such that the lengthwise direction thereof is parallel to the third direction 16, and the actuator 388 is coupled to a lower end of the support shaft 386. The actuator 388 rotates, raises, and lowers the support shaft 386. The nozzle support rod 382 is coupled perpendicular to an upper end of the support shaft 388 that is opposite to the lower end of the support shaft 386 to which the actuator 388 is coupled. The nozzle 384 is mounted on the bottom surface of a distal end portion of the nozzle support rod 382. The nozzle 384 is moved between a process position and a standby position by the actuator 388. The process position is a position where the nozzle 384 is located directly above the cup 320, and the standby position is a position where the nozzle 384 deviates from directly above the cup 320.

The chemical solution dispensing unit 380 of the substrate treating apparatus 3000 may receive the chemical solution from a chemical solution storage tank 400. The chemical solution storage tank 400 is connected to a first supply line 410 connected to the chemical solution dispensing unit 380 of the substrate treating apparatus 3000. An opening/shutting valve may be disposed in-line with the first supply line 410.

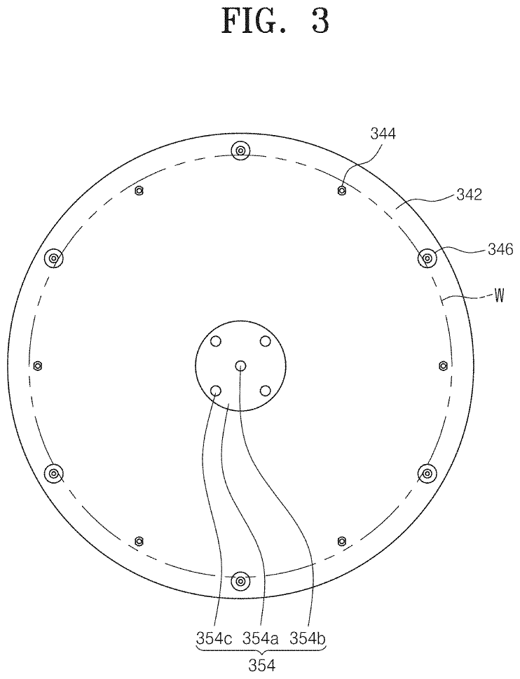

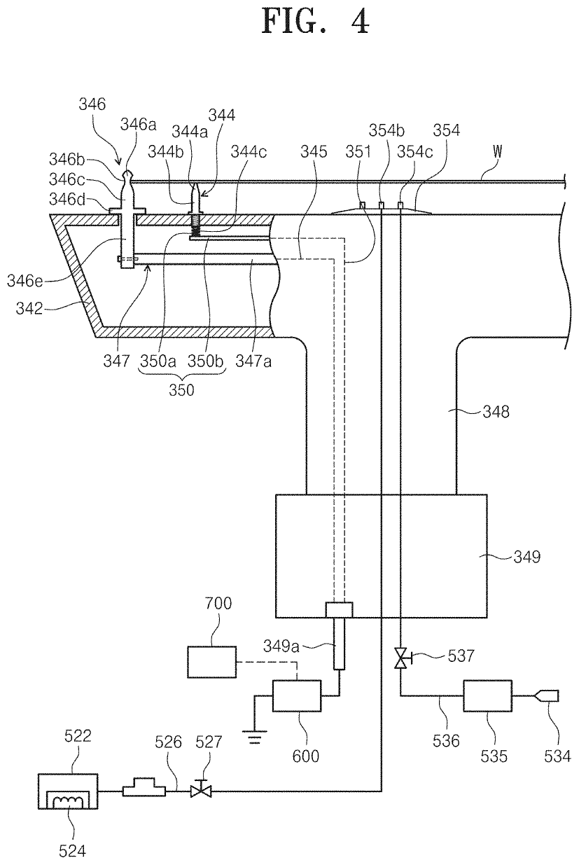

FIG. 3 is a schematic plan view illustrating the support unit 340 of the substrate treating apparatus 3000 of FIG. 2, and FIG. 4 is a schematic sectional view illustrating the inside of the support unit 340 of the substrate treating apparatus 3000 of FIG. 2. The support unit 340 of the substrate treating apparatus 3000 will be described with reference to FIGS. 3 and 4.

Referring to FIGS. 3 and 4, the support unit 340 supports and rotates the substrate W during a process. The support unit 340 has a support plate 342, support pins 344, chucking pins 346, a chucking-pin moving unit 347, and a rotary shaft 348.

The support plate 342 has an upper surface in a substantially circular shape when viewed from above. The support pins 344 protrude upward from an edge region of the upper surface of the support plate 342. The support pins 344 are spaced apart from each other by predetermined distances along the circumferential direction of the support plate 342 and support an edge region of the bottom surface of the substrate W. The support pins 344 all have the same shape and size. Each of the support pins 344 includes an upper portion 344a having a gradually increasing diameter toward the bottom and a lower portion 344b extending downward from the upper portion 344a and having a constant diameter. A cylindrical protruding portion 344c extending in the lengthwise direction of the support pin 344 is provided on the bottom surface of the lower portion 344b of the support pin 344. The protruding portion 344c has a smaller diameter than the lower portion 344b of the support pin 344. An outer surface of the support pin 344 is coated with a conductive material. For example, the conductive material may be conductive ceramics.

The chucking pins 346 protrude upward from the edge region of the upper surface of the support plate 342. The chucking pins 346 are spaced apart from each other by predetermined distances along the circumferential direction of the support plate 342. The chucking pins 346 are located farther away from the center of the support plate 342 than the support pins 344. The chucking pins 346 support a lateral portion of the substrate W such that the substrate W does not deviate from a correct position to a side when the substrate W is rotated. The chucking pins 346 all have the same shape and size. Each of the chucking pins 346 includes a support portion 346a, a central portion 346c, a fastening portion 346e, and a stopping portion 346d. The support portion 346a has a shape in which the diameter gradually decreases and then increases downward from a flat upper surface. Accordingly, the support portion 346a has a concave portion 346b that is inwardly concave when viewed from the front. The lateral portion of the substrate W placed on the support pins 344 is brought into contact with the concave portion 346b. The central portion 346c extends downward from a lower end of the support portion 346a and has the same diameter as the lower end of the support portion 346a. The fastening portion 346e extends downward from the central portion 346c. A screw hole for a coupling of the fastening portion 346e and the chucking-pin moving unit 347 is formed in the fastening portion 346e. The stopping portion 346d extends outward from the central portion 346c and has a ring shape. The stopping portion 346d is brought into close contact with the upper surface of the support plate 342 and allows the chucking pin 346 to protrude to the same height.

The chucking pin 346 may be formed of a material with corrosion resistance, fire resistance, and heat resistance, such as SIC ceramic, carbon PFA, carbon PEEK, or the like.

The chucking-pin moving unit 347 moves the chucking pins 346 between a support position and a standby position. In the support position, the chucking pins 346 are brought into contact with the lateral portion of the substrate W, and in the standby position, the chucking pins 346 provide a space wider than the substrate W such that the substrate W is placed on the support unit 340. The support position is closer to the center of the support plate 342 than the standby position. The chucking-pin moving unit 347 includes moving rods 347a, each of which is coupled with one chucking pin 346. The moving rods 347a are disposed inside the support plate 342 in the same direction as the radial direction of the support plate 342. The chucking pins 346 and the moving rods 347a may be coupled by screws.

The rotary shaft 348 is fixedly coupled to the bottom surface of the support plate 342 and supports and rotates the support plate 342. The rotary shaft 348 has a hollow cylindrical shape. The rotary shaft 348 protrudes outside the cup 320 through an opening formed in the bottom of the cup 320. A lower end of the rotary shaft 348 protruding outside the cup 320 is fixedly coupled with a motor 349. The motor 349 provides torque to the rotary shaft 348, and the rotary shaft 348 is rotatable by the torque.

A ground line 345 is connected to the chucking pin 346. The chucking pin 346 releases electric charges in the substrate W or a chemical solution L to the outside through the ground line 345. The ground line 345 is formed of a conductive material. The ground line 345 may be provided inside the moving rod 347a. The ground line 345 may be connected to a ground pin 349a. The ground pin 349a is electrically connected with the motor 349. The ground pin 349a connected with the motor 349 releases electric charges generated in the substrate W to the outside. Accordingly, electric charges in the substrate W are released to the outside through the chucking pin 346, the ground line 345, and the ground pin 349a. A current detector 600 may be installed downstream of the ground pin 349a. The current detector 600 may measure the amount of electric current released to a ground and may be implemented with a micro-current meter capable of measuring micro-current. For example, the current detector 600 may be implemented with a high-sensitivity element capable of measuring current in nA or less.

Although the current detector 600 is installed downstream of the ground pin 349a according to an embodiment, the current detector 600 may be disposed in-line with the ground line 345 and/or a ground line 351. Alternatively, even though the ground pin 349a is not provided, the current detector 600 may be disposed in-line with a line that the ground line 345 and the ground line 351 join. The current detector 600 may transfer a detected current value to a data processing unit 700. The data processing unit 700 may include a central processing unit (CPU), a read only memory (ROM), and a random access memory (RAM). The data processing unit 700 may transfer the detected current value received from the current detector 600 to the outside through an output unit (not illustrated) (e.g., a display device). The current detector 600 may detect current in real time, and the data processing unit 700 may receive and process data in real time.

A support pin ground member 350 releases electric charges in the substrate W to the outside through the support pin 344. The support pin ground member 350 includes a spring 350a and a rod 350b. The spring 350a and the rod 350b are formed of a metallic material. The rod 350b is provided in the radial direction of the support plate 342. One end of the spring 350a is connected with the support pin 344, and an opposite end of the spring 350a is connected with the rod 350b. The rod 350b may be connected to the ground pin 349a through the ground line 351. Accordingly, electric charges in the substrate W are released to the outside through the support pin 344, the spring 350a, the rod 350b, and the ground pin 349a. Unlike the above description, the spring 350a may have a hollow cylindrical shape surrounding the support pin 344. Accordingly, the spring 350a may maximize the surface making contact with the support pin 344 and may more efficiently release electric charges in the substrate W. Furthermore, the rod 350b may be directly connected with the support pin 344 without the spring 350a and may release electric charges in the substrate W to the outside.

Unlike in the above-described embodiment, the chucking pin 346 may be grounded, and the support pin 344 may not be grounded. In an embodiment, the support pin 344 may be grounded, and the chucking pin 346 may not be grounded.

A lower nozzle 354 supplies a chemical solution or a process gas to the lower surface of the substrate W placed on the support unit 340. The substrate W is located above the support plate 342 so as to be spaced apart from the upper surface of the support plate 342 by a predetermined distance, and the lower nozzle 354 supplies the chemical solution or the process gas into the space between the support plate 342 and the substrate W. The lower nozzle 354 has a jetting head 354a. The jetting head 354a has an upwardly convex shape and protrudes upward from the support plate 342. The jetting head 354a includes a plurality of discharge ports 354b and 354c. The discharge ports 354b and 354c dispense one of a plurality of chemical solutions, a rinsing solution, and a drying gas such as isopropyl alcohol vapor or nitrogen gas. A lower end of the jetting head 354a is inserted into a through-hole formed in the center of the support plate 342. The chemical solution and/or the drying gas supplied from the nozzle 384 and the lower nozzle 354 clean the substrate W while being spread from the central region to the edge region of the upper or lower surface of the substrate W by rotation of the support plate 342. Meanwhile, this embodiment is not limited to only an apparatus for cleaning both sides of a substrate and may be identically applied to a substrate rotating apparatus of a cleaning apparatus capable of cleaning only one side of a substrate. In this case, unlike the double-side cleaning apparatus, the single-side cleaning apparatus may not include the lower nozzle 354, but may include a purge unit (not illustrated) that penetrates through the rotary shaft 348 and supplies a purge gas to the rear surface of the substrate.

The lower nozzle 354 includes the first discharge port 354b installed at the center of the upper surface of the support plate 342. The first discharge port 354b is connected with a DIW supply line 526 and located at the center of the support plate 342. DIW dispensed from the first discharge port 354b cleans the bottom surface of the substrate W while being spread from the central region to the edge region of the bottom surface of the substrate W by rotation of the substrate W.

The DIW dispensed from the lower nozzle 354 may be supplied in a heated state. While the bottom surface of the substrate W is being cleaned by the lower nozzle 354, the heated DIW may not only improve cleaning efficiency, but may also perform a function of heating the substrate W.

The DIW supply line 526 is connected with a DIW supply source 522. The DIW supply source 522 is equipped with a heater 524. The heater 524 may heat DIW stored in the DIW supply source 522. Alternatively, the heater 524 may be installed on the DIW supply line 526. One end of the DIW supply line 526 is connected to the DIW supply source 522, and an opposite end of the DIW supply line 526 is connected to the first discharge port 354b. The DIW supply line 526 is connected with the first discharge port 354b via a hollow section of the support unit 340. Meanwhile, a drain line (not illustrated) branching off from the DIW supply line 526 may be further included.

A first valve 527, which is an on/off valve, is disposed in-line with the DIW supply line 526. Furthermore, a suck-back valve (not illustrated) for sucking back heated DIW remaining in the first discharge port 354b immediately after DIW is dispensed may be disposed in-line with the DIW supply line 526. The DIW supply line 526 may preferably be implemented with a pipe. Alternatively, the DIW supply line 526 may be defined by a tubular-shaped empty space in the support unit 340. The temperature of heated DIW stagnant in the DIW supply line 526 is lowered as time passes. When low-temperature DIW is dispensed onto the substrate W, efficiency in cleaning the substrate W may be lowered. The drain line (not illustrated) may be used to drain residual DIW in the DIW supply line 526 to ensure process reproducibility of heated DIW that is dispensed onto the bottom surface of the substrate W. That is, before heated DIW is dispensed onto the bottom surface of the substrate W, stagnant DIW in the DIW supply line 526 is drained for a predetermined period of time, and only DIW heated to a preset temperature by the heater 524 is supplied to the first discharge port 354b.

DIW may be heated to a temperature higher than the room temperature and may be supplied to the substrate W. Selectively, DIW may be heated to a temperature higher than the temperature of IPA supplied to the substrate W and may be supplied to the substrate W. According to an embodiment, DIW may be supplied to the bottom surface of the substrate W at a temperature of 60° C. to 80° C.

According to an embodiment, DIW is supplied to the bottom surface of the substrate W while IPA is supplied to the upper surface of the substrate W. Due to this, a cleaning process is simultaneously performed on the bottom surface of the substrate W while a drying process is performed on the upper surface of the substrate W. Furthermore, heated DIW is supplied to the bottom surface of the substrate W while IPA is supplied to the upper surface of the substrate W. In a process of drying the substrate W, the heated DIW prevents a rapid temperature drop of the surface of the substrate W due to condensate cooling depending on evaporation of the IPA. That is, the temperature of the entire substrate W is maintained in the range of 60° C. to 80° C. by dispensing the heated DIW onto the bottom surface of the substrate W while drying the substrate W by dispensing IPA and N₂ gas onto the surface of the substrate W. To allow DIW to have a temperature of 60° C. to 80° C. when supplied to the bottom surface of the substrate W, the heater 524 heats the DIW to a temperature slightly higher than the temperature of 60° C. to 80° C. The temperature range may vary depending on the progress of the drying process.

IPA produces a greater drying effect when supplied in a heated state to the substrate W. However, when liquid IPA or a mixture thereof is supplied, there is a limitation in raising the temperature of the IPA supplied to the substrate W. However, when heated DIW is supplied to the bottom surface of the substrate W while the IPA is supplied to the upper surface of the substrate W, the substrate W may be heated, and an effect similar to an effect when high-temperature IPA is supplied may be obtained. Of course, when a heated cleaning solution is supplied to the bottom surface of the substrate W while IPA in a vapor state is supplied to the upper surface of the substrate W, drying efficiency is raised, as compared with when a cleaning solution at room temperature is supplied.

Water marks and particles due to poor drying may be prevented by keeping the temperature of the substrate W constant using heated DIW during the drying process. Furthermore, as the temperature of the entire substrate W is maintained at constant temperature without a rapid temperature drop, the time taken to dry the substrate W using IPA is reduced, and thus IPA consumption is decreased.

Although it has been exemplified that heated DIW in a liquid state is used as a cleaning fluid, heated nitrogen gas or heated DIW in a vapor or mist state may be used.

The lower nozzle 354 includes the second discharge ports 354c installed around the first discharge port 354b. The second discharge ports 354c are connected with a gas supply line 536. Gas dispensed from the second discharge ports 354c makes contact with the bottom surface of the substrate W while being spread from the central region to the edge region of the bottom surface of the substrate W by rotation of the substrate W. The gas may be nitrogen gas. The gas may be a drying gas for drying the backside of the substrate W.

The gas supply line 536 is connected with a gas supply source 534. An ionizer 535 may be disposed in-line with the gas supply line 536. The ionizer 535 may ionize the gas by removing electrons from the gas. For example, the ionizer 535 may make the gas electrically positive. The electrically positive gas may make contact with the substrate W and may electrically neutralize static electricity charged on the substrate W.

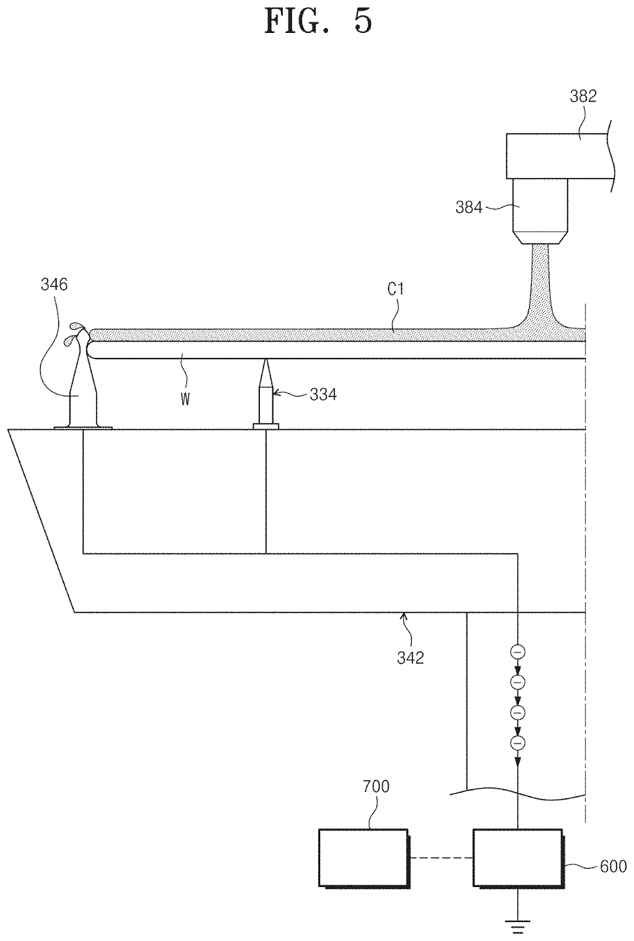

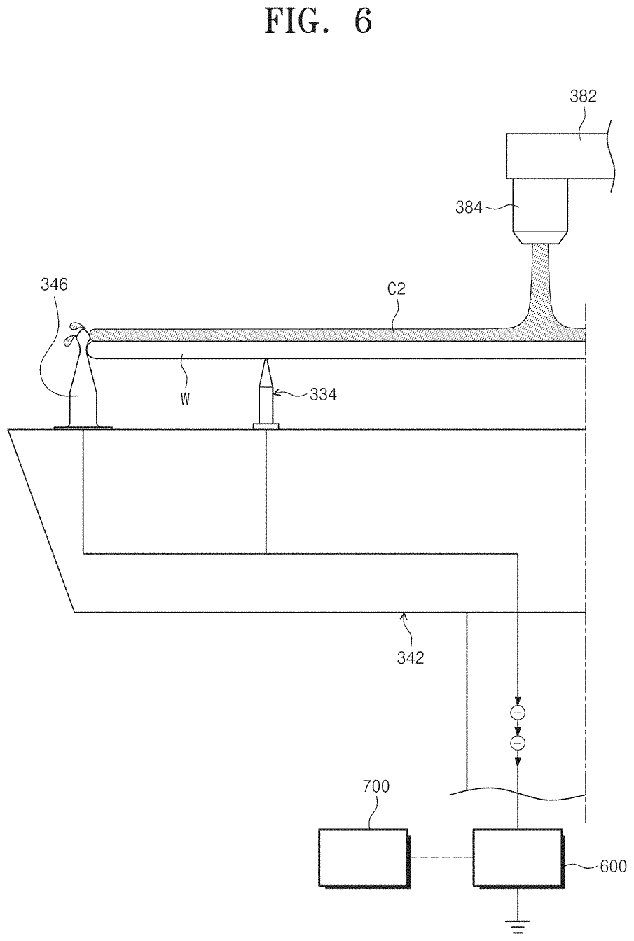

FIG. 5 is a view illustrating a state in which a first chemical solution is dispensed onto a substrate supported on the support unit provided in the substrate treating apparatus according to the embodiment of FIG. 2. FIG. 6 is a view illustrating a state in which a second chemical solution is dispensed onto the substrate supported on the support unit provided in the substrate treating apparatus according to the embodiment of FIG. 2. As illustrated in FIGS. 5 and 6, a current value detected when the first chemical solution C1 is dispensed may differ from a current value detected when the second chemical solution C2 is dispensed. This may be because the amounts of static electricity generated by friction with the substrate differ from each other due to the different types of chemical solutions.

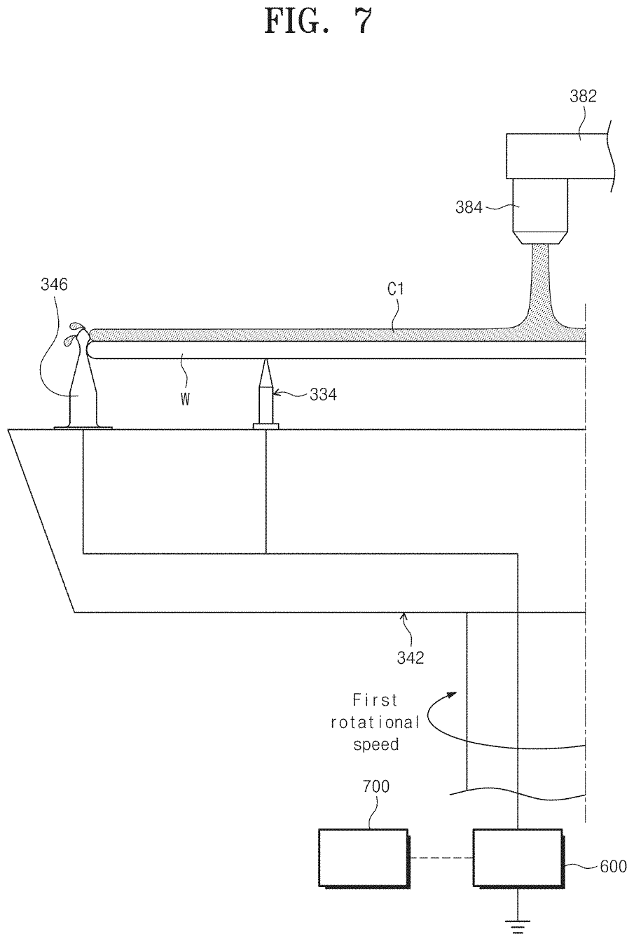

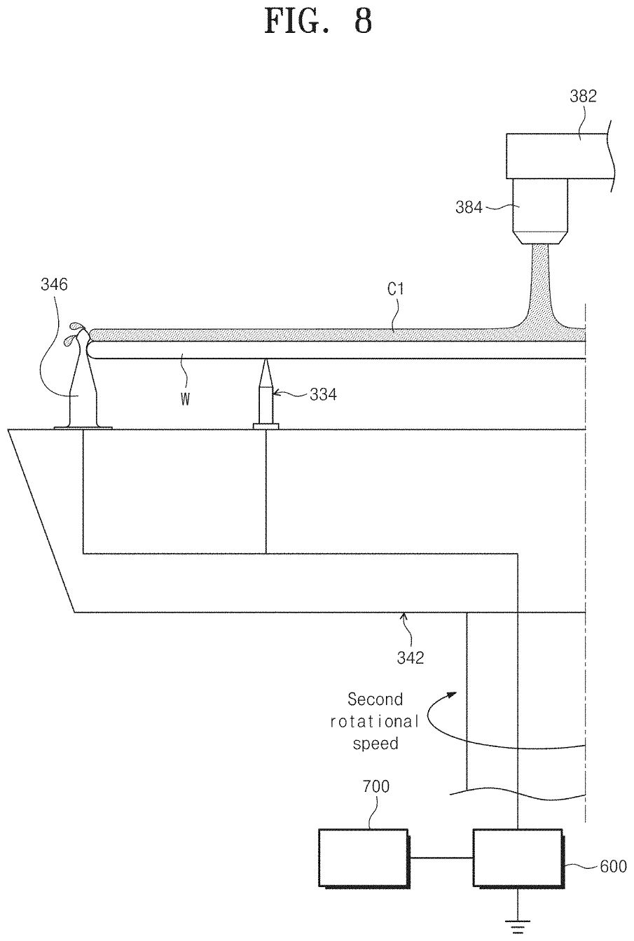

FIG. 7 is a view illustrating a state in which the first chemical solution is dispensed when a substrate supported on the support unit provided in the substrate treating apparatus according to the embodiment of FIG. 2 rotates at a first rotational speed. FIG. 8 is a view illustrating a state in which the first chemical solution is dispensed when the substrate supported on the support unit provided in the substrate treating apparatus according to the embodiment of FIG. 2 rotates at a second rotational speed. Even when the first chemical solution C1 is identically dispensed as illustrated in FIGS. 7 and 8, different current values may be detected depending on the rotational speeds. This may be because the amounts of static electricity generated by friction of the first chemical solution with the substrate differ from each other depending on the rotational speeds of the substrate. In an embodiment, the amount of current detected may be increased as the rotational speed of the substrate is increased. That is, the rotational speed of the substrate may be estimated from a detected current value.

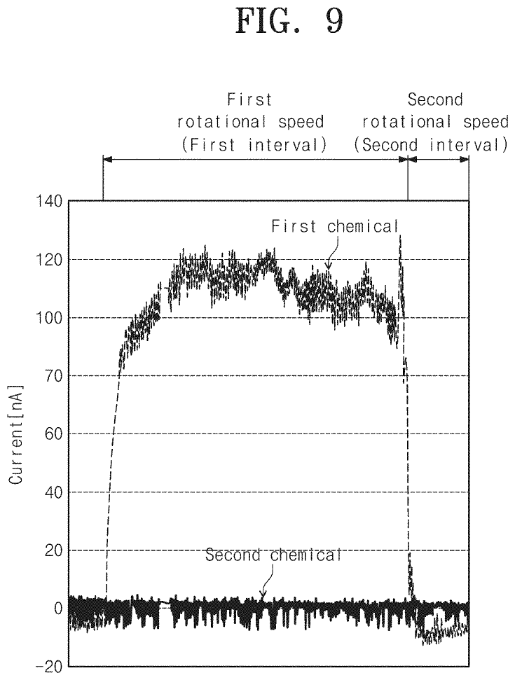

FIG. 9 is a graph depicting the amounts of current by electric charges escaping through a ground. It can be seen that there is a difference in detected current of 100 nA or more between the first chemical solution and the second chemical solution even when a substrate identically rotates at the first rotational speed. Furthermore, it can be seen that in the case of the first chemical solution, there is a difference in detected current of 100 nA or more between when the substrate rotates at the first rotational speed and when the substrate rotates at the second rotational speed. However, in the case of the second chemical solution, there is no significant difference in detected current between when the substrate rotates at the first rotational speed and when the substrate rotates at the second rotational speed. Based on these results, in the case of substituting a liquid film with the second chemical solution instead of the first chemical solution, whether the liquid film is substituted with the second chemical solution is able to be verified by the amount of detected current. In this case, it is unnecessary to excessively use the second chemical solution, and thus the usage of the second chemical solution may be reduced.

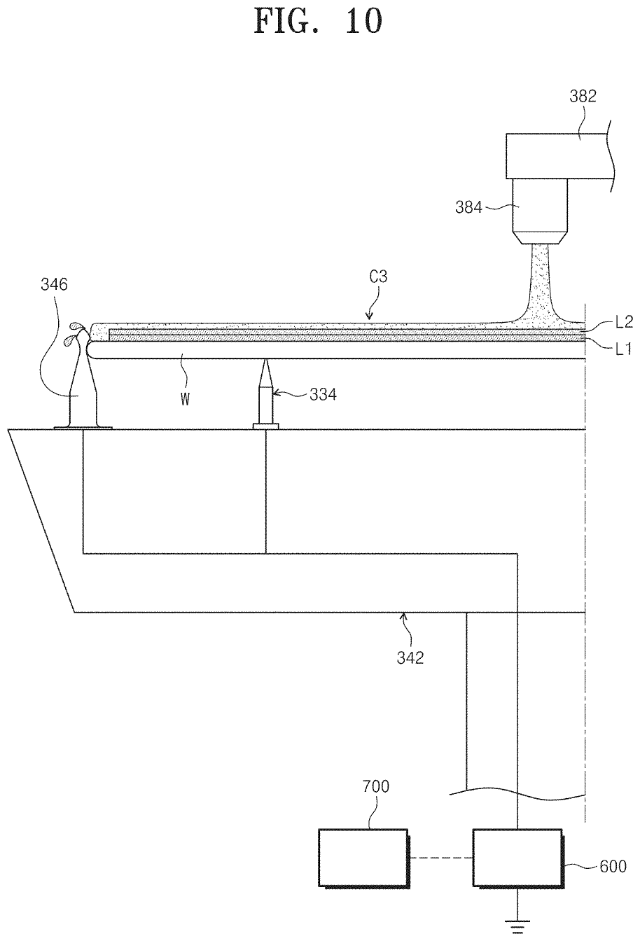

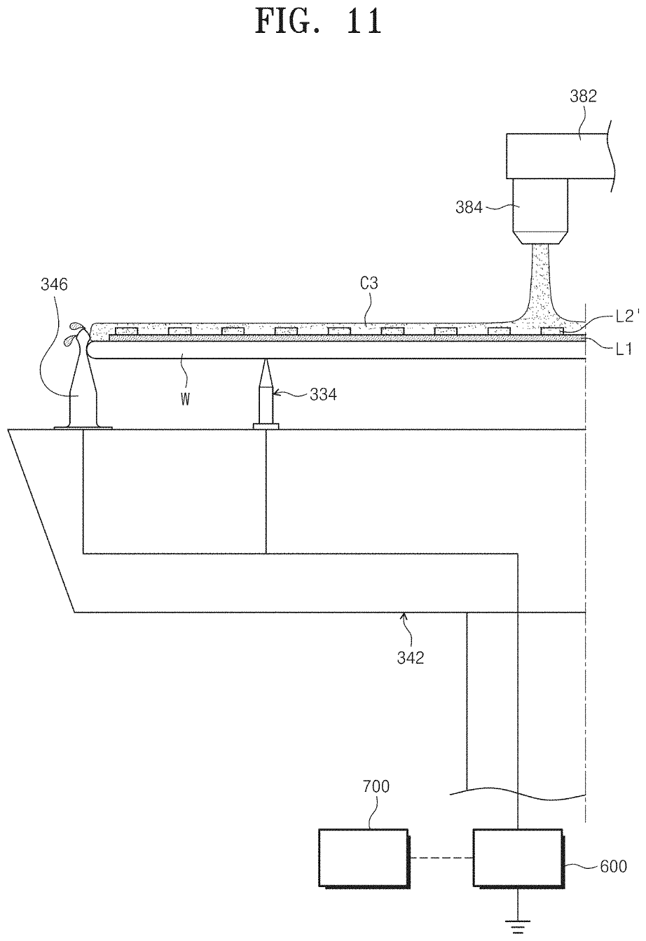

FIG. 10 is a view illustrating a state in which a third chemical solution is dispensed onto a substrate supported on the support unit provided in the substrate treating apparatus according to the embodiment of FIG. 2. FIG. 11 is a view illustrating a state in which a film is changed by the third chemical solution continually dispensed in the state of FIG. 10. Even when the third chemical solution C3 is identically dispensed as illustrated in FIGS. 10 and 11, different current values may be detected depending on states of the film. This may be because the amounts of static electricity generated differ from each other due to a difference in reaction and friction between the film exposed on the substrate and the chemical solution. Accordingly, whether the film is processed to a desired degree may be determined through detection of current. That is, the data processing unit 700 may actively determine an end point based on a detected current value.

Although not described above, when the amount of detected current exceeds a preset threshold value, a possibility of a defective wafer due to arcing may be recognized, and the yield rate may be raised accordingly.

Although not described above, a physical state, such as the temperature of a chemical solution, may be estimated from the amount of detected current.

When an excessive amount of current is detected, static electricity may be reduced by turning on the ionizer 535 and supplying positively ionized gas to the bottom surface of a substrate.

According to the various embodiments of the inventive concept, the substrate treating apparatus and method may improve efficiency in treating a substrate.

According to the various embodiments of the inventive concept, the substrate treating apparatus and method may obtain data including information about a substrate from a component applied to release static electricity generated by a chemical solution dispensed onto the rotating substrate and other causes and may utilize the obtained data to efficiently treat the substrate.

Effects of the inventive concept are not limited to the aforementioned effects, and any other effects not mentioned herein may be clearly understood from this specification and the accompanying drawings by those skilled in the art to which the inventive concept pertains.

The above description exemplifies the inventive concept. Furthermore, the above-mentioned contents describe embodiments of the inventive concept, and the inventive concept may be used in various other combinations, changes, and environments. That is, variations or modifications can be made to the inventive concept without departing from the scope of the inventive concept that is disclosed in the specification, the equivalent scope to the written disclosures, and/or the technical or knowledge range of those skilled in the art. The written embodiments describe the best state for implementing the technical spirit of the inventive concept, and various changes required in specific applications and purposes of the inventive concept can be made. Accordingly, the detailed description of the inventive concept is not intended to restrict the inventive concept in the disclosed embodiment state. In addition, it should be construed that the attached claims include other embodiments.

While the inventive concept has been described with reference to embodiments, it will be apparent to those skilled in the art that various changes and modifications may be made without departing from the spirit and scope of the inventive concept. Therefore, it should be understood that the above embodiments are not limiting, but illustrative.

1. An apparatus for treating a substrate, the apparatus comprising:
a cup having a process space therein;
a support unit configured to support the substrate in the process space, the support unit including a rotatable support plate;
a chemical solution dispensing unit configured to dispense a chemical solution onto the substrate supported on the support unit; and
a conductive member configured to make direct contact with at least one of the substrate or the chemical solution dispensed onto the substrate,
wherein the conductive member is grounded, and
wherein a current detector is provided on a ground path between the grounded conductive member and a ground.

2. The apparatus of claim 1, wherein the conductive member is a chucking pin configured to support a side surface of the substrate.

3. The apparatus of claim 1, wherein the support unit includes a plurality of support pins provided on the support plate and configured to support the substrate located above the support plate, and
wherein the conductive member is implemented with at least one of the support pins.

4. The apparatus of claim 1, wherein the current detector is implemented with a high-sensitivity element configured to measure current in nano Ampere (nA) or less.

5. The apparatus of claim 1, wherein the support plate is rotatable at a first rotational speed and a second rotational speed lower than the first rotational speed.

6. The apparatus of claim 1, wherein the chemical solution dispensing unit dispenses two or more different chemical solutions.

7. The apparatus of claim 1, wherein the current detector detects a current value in real time while the chemical solution is dispensed onto the substrate.

8. The apparatus of claim 1, further comprising:
a data processing unit configured to process a current value detected by the current detector.

9. The apparatus of claim 8, wherein the data processing unit determines that the substrate is defective, when the detected current value is greater than or equal to a preset threshold value.

10. The apparatus of claim 8, wherein the chemical solution dispensing unit is configured to dispense a first chemical solution and a second chemical solution different from the first chemical solution, and the first chemical solution dispensed onto the substrate is substituted with the second chemical solution, and
wherein the data processing unit determines that the first chemical solution is substituted with the second chemical solution, when a change in the detected current value is greater than or equal to a preset value in a process in which the first chemical solution is substituted with the second chemical solution.

11. The apparatus of claim 8, wherein the data processing unit determines that the substrate is completely treated with the chemical solution, when a change in the detected current value is greater than or equal to a preset value in a process in which the substrate is treated with the chemical solution.

12.-18. (canceled)

19. An apparatus for treating a substrate, the apparatus comprising:
a cup having a process space therein;
a support unit configured to support the substrate in the process space, the support unit including a support plate rotatable at a first rotational speed and a second rotational speed lower than the first rotational speed; and
a chemical solution dispensing unit configured to dispense a first chemical solution and a second chemical solution different from the first chemical solution onto the substrate supported on the support unit,
wherein the support unit further includes:
a chucking pin configured to support a side surface of the substrate; and
a plurality of support pins provided on the support plate and configured to support the substrate located above the support plate,
wherein the chucking pin and at least one of the plurality of support pins are grounded, and
wherein the apparatus further comprises:
a current detector provided on a ground path between the grounded chucking pin or the at least one grounded support pin and a ground and configured to measure current in nano Ampere (nA) or less; and
a data processing unit configured to process a current value detected by the current detector.

20. The apparatus of claim 19, wherein the current detector detects a current value in real time while the first or second chemical solution is dispensed onto the substrate, and
wherein the data processing unit:
determines that the substrate is completely treated with the first chemical solution, when a change in the detected current value is greater than or equal to a preset value in a process in which the substrate is treated with the first chemical solution; and
determines that the first chemical solution is substituted with the second chemical solution, when a change in the detected current value is greater than or equal to a preset value in a process in which the first chemical solution is substituted with the second chemical solution.
